(19) United States
(12) Patent Application Publication
(10) Pub. No.: US 2008/0055855 A1
(43) Pub. Date: Mar. 6, 2008

(54) HEAT SINK FOR ELECTRONIC COMPONENTS

(76) Inventors: Vinod Kamath, Raleigh, NC (US); Jason Aaron Matteson, Raleigh, NC (US)

Correspondence Address: IBM CORPORATION (SS/NC);c/o STREETS & STEELE, 13831 NORTHWEST FREEWAY, SUITE 355, HOUSTON, TX, 77040, US

(21) Appl. No.: 11/470,530

(22) Filed: Sep. 6, 2006

(51) Int. Cl. H05K 7/20

(52) U.S. Cl. 361/700

(57) ABSTRACT

Heat sinks and methods are provided for improved cooling of heat-generating components. In one embodiment, a heat sink includes a base having a first wall, a second wall, and a plurality of heat pipes sandwiched therebetween. The first and second walls, optionally plates, are spaced apart to provide an airflow pathway through the base. An outer cooling fin structure is disposed on the second wall, and an optional inner cooling fin structure may be disposed on the first wall. A plurality of perforations and/or a plurality of grooves may also be formed on the walls. The heat sink is secured to a chassis with the first wall in thermal contact with a CPU. Air flows through the cooling fin structure(s), as well as through the base, grooves, and holes. The airflow through the base, grooves, and holes improves cooling and lowers the impedance of the heat sink.

### BACKGROUND OF THE INVENTION

1. Field of the Invention

The present invention relates to heat sinks for cooling heat-generating electronic components.

2. Description of the Related Art

Computer systems contain heat-generating components such as CPUs, and must be cooled to prevent overheating and potential component failure. Proper cooling is especially important for rack mounted servers, such as server blades, due to their high-density, high-powered configurations. A rack system generally includes one or more fans or blowers for generating air flow through the rack. The airflow passes through server blades and across one or more heat sinks within the server blades. A conventional heat sink for cooling a CPU generally includes a base mounted in thermal contact with the CPU, and a plurality of cooling fins disposed on the base. The base conducts heat from the CPU to the cooling fins, while air flowing through the cooling fins carries heat away from the heat sink. The design and performance of a heat sink is critical, because modern servers have very little thermal design margin. Due to the compact arrangement of a blade server system, it is important to maximize cooling efficiency and minimize air flow impedance of heat sinks and other components.

One type of conventional heat sink has a substantially solid metal base disposed between the CPU and the cooling fins. The solid metal base acts as a conductor between the CPU and the cooling fins. Ultra-dense blade applications often use heat sinks having more effective, but costly, vapor chamber bases. A vapor chamber has an internal wicked structure that houses a working fluid. The working fluid is heated by the CPU and vaporizes. The vapor cyclically fills the chamber, condenses on the walls of the chamber, and is pulled through the wicked structure back toward the CPU. The working fluid thereby extracts heat energy from the CPU, dissipates it through the base, and transfers it to the cooling fins. While these conventional bases work for their intended purposes, their design is not fully optimized. In particular, the base of a conventional heat sink is an obstacle that impedes the flow of air in the vicinity of the heat sink. Furthermore, a conventional base conducts heat to a cooling fin structure useful for cooling a CPU, but the base, itself, does not greatly contribute any actual cooling.

As the market for ultra dense blade servers continues to grow, cost reductions and performance improvements are essential. Therefore, there is an ongoing need for improved heat sinks and cooling systems. It is desirable for these heat sinks and cooling systems to maximize cooling power and efficiency, as well as to minimize the air flow impedance, weight, and cost.

### SUMMARY OF THE INVENTION

The present invention includes heat sinks and methods for improved cooling of heat-generating electronic components. Generally, a heat sink base may include first and second walls spaced apart to define an airflow path through the base. One or more heat pipes are sandwiched between the first and second walls. The first wall is configured for direct thermal contact with the heat-generating component. A cooling fin structure is in direct thermal contact with the second wall.

In one embodiment, a heat sink according to the invention may be configured for use with a blade server. The blade server includes a housing, a chassis, and a CPU disposed on the chassis. The heat sink includes a base secured to the chassis and an outer cooling fin structure secured to the base. The base includes an inner plate in thermal contact with the CPU, an outer plate, a plurality of heat pipes disposed between the inner and outer plates, and an airflow path through the heat sink base between the inner plate and the outer plate.

In another embodiment, a method is provided for cooling a heat-generating component disposed in a computer housing. A CPU is thermally contacted by an inner wall. An outer cooling fin structure is contacted by an outer cooling fin structure. Heat is conducted from the inner wall to the outer wall through one or more heat pipes. Air is passed between the inner and outer walls, and also through the outer cooling fin structure.

### BRIEF DESCRIPTION OF THE DRAWINGS

FIG. 1 is a side elevation view of an exemplary server blade having a pair of heat sinks according to the invention.

FIG. 2 is a view of one of the heat sinks taken along section A-A of FIG. 1.

FIG. 3 is a perspective view of the heat sink as viewed from one end, looking downward on the outer cooling fin structure.

FIG. 4 is a perspective view of the heat sink, flipped upside down with respect to the view of FIG. 3.

FIG. 5 is a perspective view of the heat sink as viewed from another end, looking downward on the outer cooling fin structure.

FIG. 6 is a perspective view of the base with the outer plate removed to further illustrate the orientation of the heat pipes.

FIG. 7 is a perspective view of an alternative configuration of the base having a plurality of perforations in the plates.

FIG. 8 is a view of an alternative configuration of a base having an outer wall, an inner wall, and a plurality of grooves.

FIG. 9 is a flowchart describing a method of cooling a CPU according to one embodiment of the invention.

### DETAILED DESCRIPTION OF PREFERRED EMBODIMENTS

The present invention includes the provision of heat sinks and methods for improved cooling of heat-generating electronic components, such as computer CPUs. A heat sink according to the invention may include an improved heat sink base mated with one or more conventional cooling fin structures. In one embodiment, a heat sink base includes a plurality of heat pipes sandwiched between first and second parallel plates. The base is mounted to a chassis with the first plate in thermal contact with a CPU. A cooling fin structure is mounted on one or both plates. While air flows through the cooling fin structures, air also flows through the base along one or more airflow paths between the plates. The airflow through the base lowers the overall air flow impedance of the heat sink and increases the cooling of the CPU. An optional plurality of grooves disposed in the surfaces of the plates are preferably oriented in the direction of airflow, to further lower the impedance of the heat sink, and to improve local heat transfer coefficients by breaking stagnant air flow boundary layers. The grooves may be disposed on interior surfaces of the plates, to increase airflow through the base and to allow air to pass between the plates and the heat pipes. Grooves may also be disposed on outer surfaces of the plates. Vents or holes in the plates can further break stagnant boundary layers and reduce the pressure drop through the heat sink.

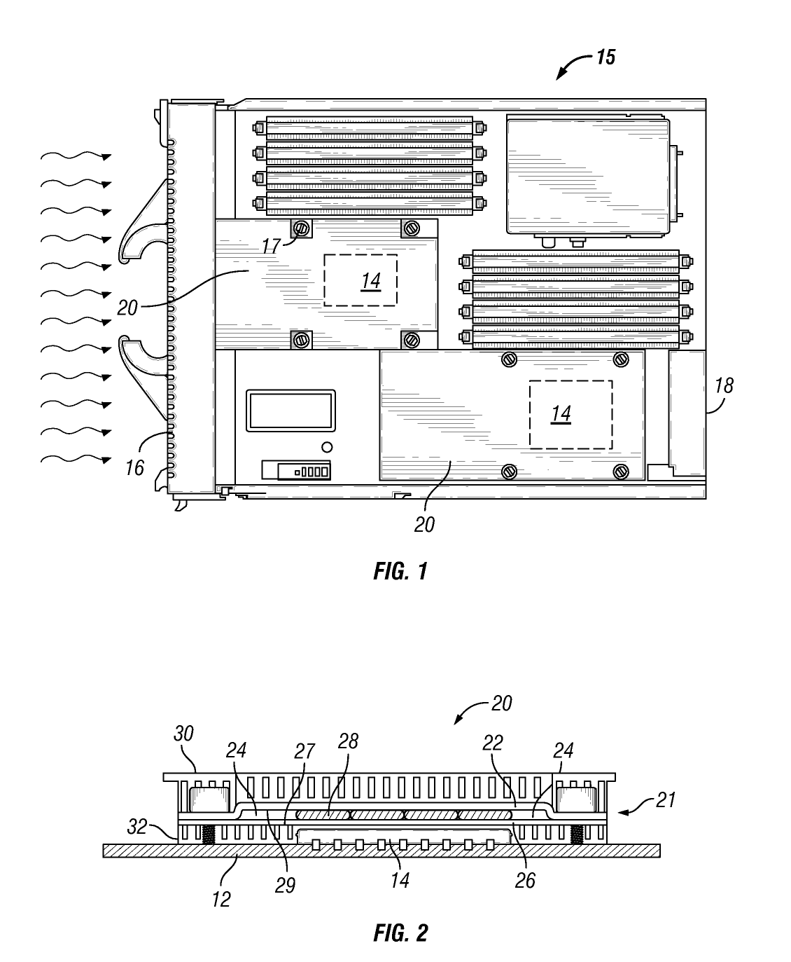

FIG. 1 is a side elevation view of an exemplary server blade 15 having a pair of heat sinks 20 according to the invention. Each heat sink 20 is secured to a chassis 12 and disposed in thermal contact with a CPU 14 disposed between each chassis 12 and heat sink 20. Threaded connectors 17 are used to removably secure the heat sink 20 to the chassis 12, though other suitable connecting means are known in the art. Airflow enters the server blade 15 at an upstream end 16 and exits at a downstream end 18. Some airflow passes through the heat sinks 20 to cool the CPUs 14. Airflow through the server blade 15 must pass through the heat sinks 20 and many other electronic components disposed on the chassis 12, so it is desirable to minimize the impedance of air flow through these components.

FIG. 2 is a partial cross-sectional view of the server blade 15 taken along section A-A of FIG. 1 to show one of the heat sinks 20 The heat sink 20 has a base 21 that includes a first plate 26 and a second plate 22. By convention, the first plate 26 is mounted closer to the chassis 12 than the second plate 22, and, therefore, the first plate 26 may be alternately referred to as the “inner” plate and the second plate 22 may be alternately referred to as the “outer” plate in the embodiment shown. More generally, the first and second plates 26, 22 are one embodiment of walls, and may alternately be referred to as inner and outer walls 26, 22. Four heat pipes 28 sandwiched between the first plate 26 and the second plate 22. The first plate 26 is in thermal contact with the CPU 14. An outer cooling fin structure 30 is secured to the base 21 in thermal contact with the second plate 22, and an optional inner cooling fin structure 32 is disposed on the base 21 in thermal contact with the first plate 26. The close spacing between the heat pipes 28 near the end of the heat sink 20 shown aligns the heat pipes 28 opposite the CPU 14, providing a relatively short, direct heat conduction path from the CPU 14 to the heat pipes 28 through the first plate 26. The heat pipes 28 have closed ends and contain a working fluid that is heated by the CPU 14 through the first plate 26. As the working fluid heats up it vaporizes, distributing the vapor and the heat carried by the vapor throughout the heat pipes 28. The heat pipes 28 thereby promote a more uniform thermal distribution throughout the base 21. A gap 24 between the plates 22, 26 allows air to flow through the base 22 (into the page) between interior surfaces 27, 29. The ability for air to flow through the base 22 reduces the air flow impedance of the heat sink 20 and improves its cooling performance. The spacing of the plates 22, 26 may be selected to control the degree of airflow that may pass through the base 22. Generally, increasing the gap 24 reduces the impedance of the base 21.

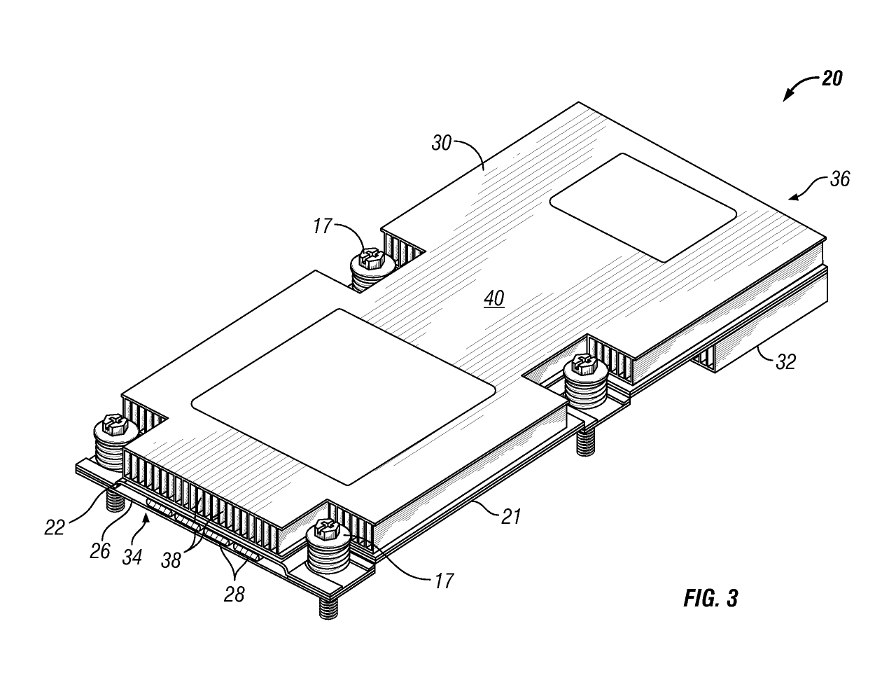

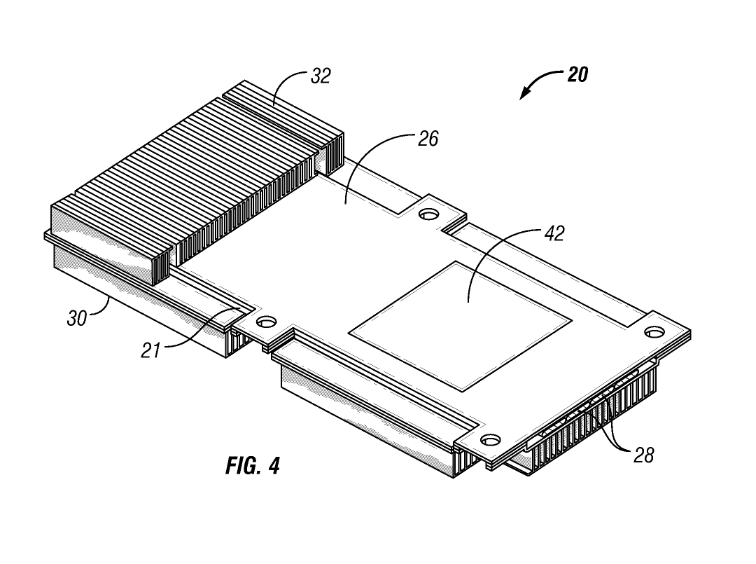

FIG. 3 is a perspective view of the heat sink 20, looking downward on the outer cooling fin structure 30. The outer cooling fin structure 30 extends the full length of the base 21, to maximize the contact area and the corresponding extent of heat transfer between the second plate 22 and the outer cooling fin structure 30. The outer cooling fin structure 30 includes a plurality of fins 38 for conducting heat away from the base 21. Air flowing between the fins 38 from an end 34 to another end 36 carries heat away from the heat sink 20. An optional web or plate 40 bridges the fins 38 and provides additional surface area for cooling and structural support for the fins. Other cooling fin structures may optionally be used that have a plurality of cooling fins without a web or plate. The heat pipes 28 are closely spaced at the end 34, with little or no gap between each of the heat pipes 28.

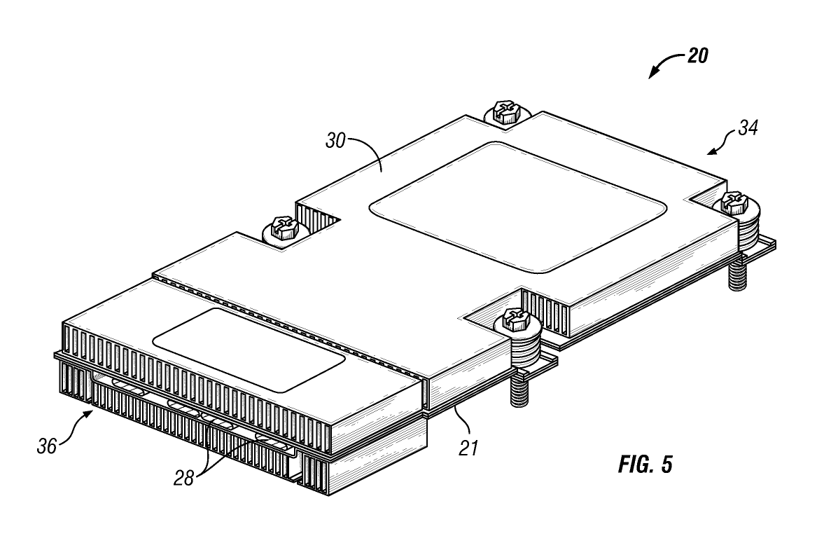

FIG. 4 is a perspective view of the heat sink 20, flipped upside down with respect to the view of FIG. 3. A CPU contact location 42 is indicated on the first plate 26, where the CPU 14 (FIG. 2) thermally contacts the first plate 26. The inner cooling fin structure 32 is optionally similar to the outer cooling fin structure 30, except that the inner cooling fin structure 32 only extends a fraction of the distance along the base 21, in order to avoid interference with the CPU 14 at the CPU contact location 42. Although the inner cooling fin structure 32 does not have as much contact area with the first plate 26 as the outer cooling fin structure 30 has with the second plate 22, the inner cooling fin structure increases the cooling capacity of the heat sink 20.

FIG. 5 is a perspective view of the heat sink 20 as viewed from the end 36 opposite the end 34, looking downward on the outer cooling fin structure 30. A spacing between the heat pipes 28 is greater at the end 36 than at the end 34 (FIG. 3). The wider spacing disperses heat, to increase the cooling performance of the heat sink 20 and to minimize hot spots along the base 21. Other heat pipe patterns and structures may be similarly implemented without departing from the invention.

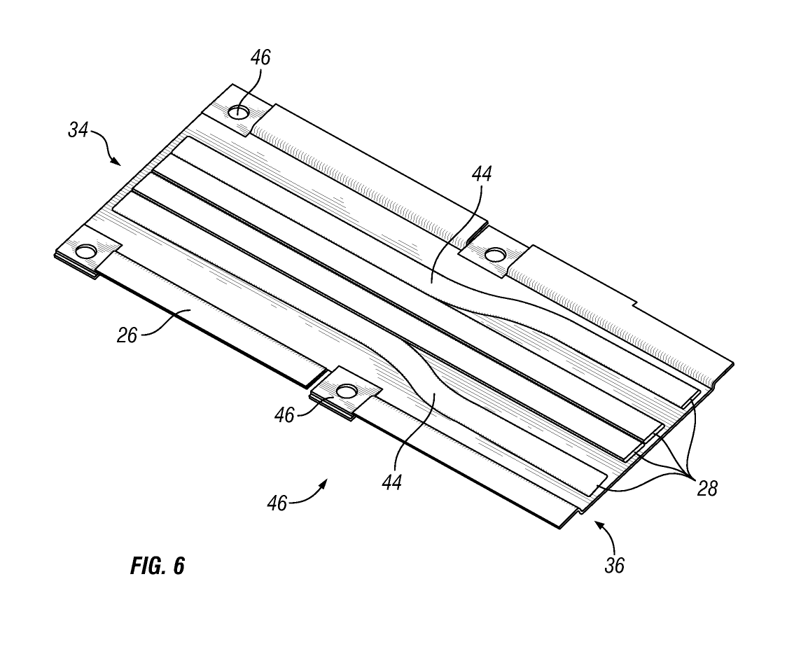

FIG. 6 is a perspective view of the base 21 without the second plate 22, to further illustrate the orientation of the heat pipes 28. Two of the heat pipes 28 have bends 44. Alternative heat pipe orientations may be configured. For example, heat pipes in other embodiments may have a greater or lesser degree of bend, and may be bent in multiple locations. Alternatively, the heat pipes may be substantially straight but angled away from one another, so that a spacing between the heat pipes increases from one end of the base to the other. A greater or lesser number of heat pipes may also be selected according to the application. If fabrication could be accomplished efficiently, a plurality of heat pipes could be replaced by a complex heat pipe configuration, such as a single multi-branched heat pipe or overlapping heat pipes. Furthermore, the heat pipes may have any of a variety of cross-sectional configurations. For example, the heat pipes may initially be fabricated with a circular cross section. Then, the heat pipes may be partially flattened during the manufacture to create a flatter surface for increasing the contact area with the plates.

Referring generally to FIGS. 1-6, the use of separate plates 22, 26 as walls of the base facilitates the manufacture and assembly of the base 21. The individual plates and the individual heat pipes 28 may be manufactured separately. The heat sink 20 may be assembled by disposing the heat pipes 28 on the first plate 26 and then stacking the second plate 22 over the first plate 26, to sandwich the heat pipes 28. The plates 22, 26 may be joined by tack welding, brazing, gluing, or other joining means known in the art. If soldered, the solder need not appreciably fill any voids, such as between the heat pipes 28. In one manufacturing technique, beaded soldered is laid along the opposing surfaces of the heat pipes 28 prior to sandwiching the heat pipes 28 between the plates 22, 26. Soldering the heat pipes to the plates increases the heat transfer by conduction. The resulting sandwich may be heated to activate the solder. Alternatively or additionally, the plates 22, 26 may be wholly secured to one another by the threaded fasteners 17 used to secure the heat sinks 20 to the chassis 12 (FIGS. 1 and 3). The threaded fasteners 17 pass through holes 46 on the first plate 26 and corresponding holes on the second plate 22.

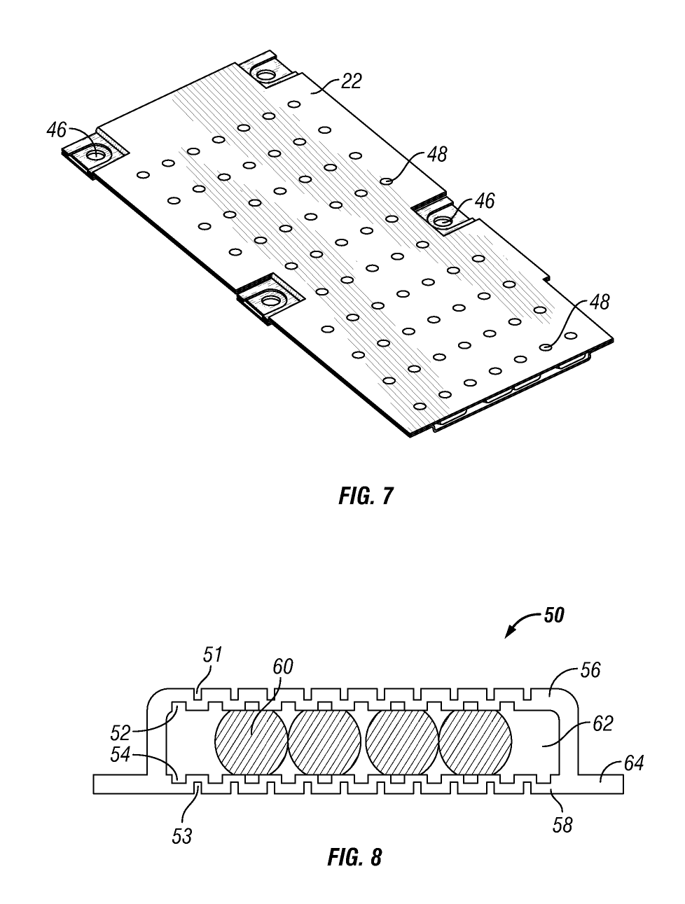

FIG. 7 is a perspective view of an alternative configuration of the base 21 having a plurality of perforations or holes 48 in the plates 22, 26. As shown in the figure, the holes 48 pass through the second plate 22, and may also pass through the first plate 26. The holes 48 break stagnant air flow boundary layers to increase heat transfer and reduce the pressure drop through the heat sink. The holes 48 may be formed by drilling, stamping, or other means known in the art for forming holes.

In other embodiments, first and second walls of a base may alternatively be formed as part of a unitary structure, rather than as separate plates. For example, a base having a hollow rectangular cross section may be extruded or otherwise formed, wherein opposing sides of the rectangular cross section serve as outer and inner walls defining at least a portion of an airflow path through the base. One or more heat pipes may then be inserted between the walls of the base. Mounting holes may be formed in extruded flanges on the base to accommodate threaded fasteners. One of ordinary skill in the art may recognize alternative ways to fabricate a heat sink base according to the principles of the invention taught herein.

FIG. 8 is a view of an alternative configuration of a base 50 having a first wall 58, a second wall 56, and a plurality of grooves 51, 52, 53, 54 on the wall surfaces. The sets of grooves on the wall surfaces 51-54 are generally aligned with a direction of airflow through the base 50 (into the page). The second wall 56 includes a set of exterior grooves 51 on one surface and interior grooves 52 on the opposing surface. The first wall 58 includes a set of exterior grooves 53 on one surface and interior grooves 54 on the opposing surface. A plurality of heat pipes 60 are sandwiched between the first wall 56 and the second wall 58. Air may flow between the first and second walls 58, 56 along airflow paths 62 (into the page), which increases the cooling capacity and lowers the impedance of the base 50. The heat pipes 60 are closely spaced at the end of the base 50 shown in the figure, but may spread outwardly closer to the opposite end of the base 50, similar to the heat pipes 28 of FIG. 6. The grooves 51-54 provide additional airflow paths along the base 50, further increasing the cooling capacity and reducing the airflow impedance of the base 50. In particular, some of the interior grooves 52, 54 provide airflow paths between the walls 56, 58 and the heat pipes 60 at an interface between the walls 56, 58 and the heat pipes 60. A heat sink may be formed by attaching one or more cooling fin structures to the base 50. A cooling fin structure is secured to the second wall 56 of the base 50, and another cooling fin structure may be secured to the first wall 58 of the base 60. Tabs 64 are provided for mounting the heat sink.

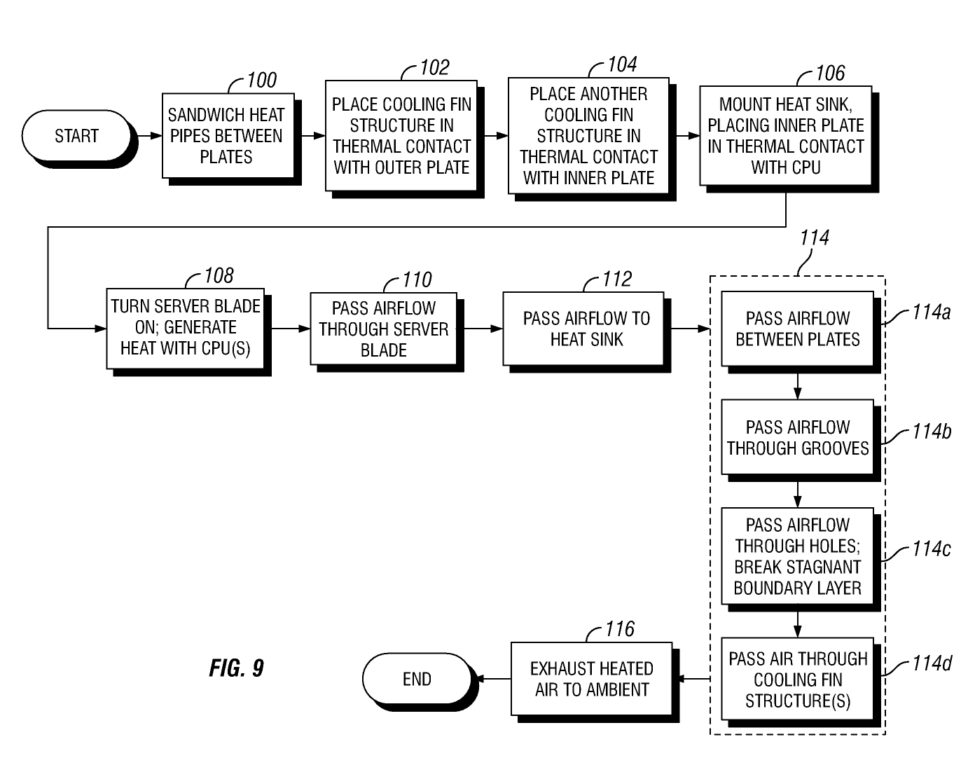

FIG. 9 is a flowchart describing a method of cooling a CPU according to one embodiment of the invention. The method may be implemented or at least visualized in terms of using a heat sink such as described in the embodiments of FIGS. 1-8. In step 100, heat pipes are sandwiched between two walls or plates, to form a base. In step 102, a cooling fin structure is mounted to the base in thermal contact with a second plate. Optionally, another cooling fin structure may be mounted to the base in thermal contact with a first plate in step 104. Steps 100-104 may occur, for example, by virtue of selecting, purchasing, assembling, or installing a heat sink according to the invention. In step 106, that heat sink is mounted to a chassis of a computer, such as a server blade, in thermal contact with a CPU. In step 108, the server may be powered “ON,” and the CPU will begin generating heat. The CPU may generate greater amounts of heat and potentially hotter temperatures during periods of increased processing by the CPU.

It is desirable to always maintain proper cooling of the server blade, as well as heat-generating components like the CPU, during even the most power-intensive periods. Thus, air is passed through the server blade in step 110. The airflow passing through the server blade will typically travel along various flow paths throughout the server blade as it passes between the various components. Some of this airflow will pass through the heat sink in step 112. In step 114, some air passes through the heat sink. Steps 114a through 114b occur substantially simultaneously. In step 114a, some of the airflow passes between the plates of the heat sink. In step 114b, some of the airflow passes through grooves on the plates. In step 114c, some of the airflow passes through or over holes or perforations in the plates, which desirably breaks up stagnant boundary layers. In step 114d, some of the airflow passes through the cooling fin structures. The overall airflow in step 114 carries away heat-generated by the CPU. Because air is allowed to flow through the base (step 114a), as well as through the grooves (114b), the overall airflow impedance of the heat sink is reduced. The reduced airflow impedance makes more efficient use of the airflow through the server blade. In step 116, the heated air exits the server blade. The heated air will ultimately be exhausted to ambient.

Although the exemplary embodiments discussed herein are primarily directed to the cooling of a CPU, those skilled in the art will recognize that the invention may also be applied to the cooling of other heat-generating electronic components and in other electronic devices. Thus, the invention is not limited to the cooling of a CPU in a server blade.

The terms “comprising,” “including,” and “having,” as used in the claims and specification herein, shall be considered as indicating an open group that may include other elements not specified. The terms “a,” “an,” and the singular forms of words shall be taken to include the plural form of the same words, such that the terms mean that one or more of something is provided. The term “one” or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition or step being referred to is an optional (not required) feature of the invention.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A heat sink for cooling a heat-generating component of a computer, comprising:
a base having first and second walls spaced apart to define an airflow path through the base, wherein the first wall is configured for thermal contact with the heat-generating component;
a cooling fin structure in thermal contact with the second wall; and
one or more heat pipes disposed in thermal contact between the first and second walls.

2. The heat sink of claim 1, further comprising:
a cooling fin structure in thermal contact with the first wall of the base.

3. The heat sink of claim 1, further comprising a plurality of grooves disposed on at least one of the first and second walls.

4. The heat sink of claim 3, wherein the plurality of grooves are interior to the airflow path.

5. The heat sink of claim 1, wherein the first wall comprises an inner plate and the second wall comprises an outer plate.

6. The heat sink of claim 1, further comprising a plurality of perforations through one or both of the first and second walls.

7. The heat sink of claim 1, wherein the one or more heat pipes do not penetrate the first or second walls.

8. The heat sink of claim 1, wherein a downstream spacing of the heat pipes is larger than an upstream spacing of the heat pipes.

9. A method of cooling a heat-generating component disposed in a computer housing, comprising:
thermally contacting a first wall with the heat-generating component;
thermally contacting a second wall with an outer cooling fin structure;
conducting heat from the first wall to the second wall through one or more heat pipes;
passing air between the first and second walls; and
passing air through the outer cooling fin structure.

10. The method of claim 9, further comprising:
thermally contacting the first wall with an inner cooling fin structure; and
passing air through the inner cooling fin structure.

11. The method of claim 9, further comprising passing air through a plurality of grooves disposed on one or both of the first and second walls.

12. The method of claim 9, wherein the plurality of grooves are substantially aligned with the direction of the airflow between the first and second walls.

13. The method of claim 9, wherein the plurality of grooves are disposed between the first and second walls.

14. The method of claim 9, further comprising passing air through a plurality of perforations disposed on one or both of the first wall and the second wall.

15. A blade server comprising:
a housing;
a blower for passing air through the housing;
a chassis;
a CPU disposed on the chassis;
a heat sink base secured to the chassis, the heat sink base including an inner wall in thermal contact with the CPU, an outer wall, a plurality of heat pipes disposed between the inner and outer walls, and an airflow path through the heat sink base between the inner wall and the outer wall; and
an outer heat sink structure disposed on the outer wall.

16. The blade server of claim 15, further comprising:
an inner cooling fin structure disposed on the inner wall.

17. The blade server of claim 15, wherein the heat sink base further comprises a plurality of perforations disposed on one or both of the inner wall and the outer wall.

18. The blade server of claim 15, wherein the heat sink further comprises a plurality of grooves disposed on one or both of the inner wall and the outer wall.

19. The blade server of claim 18, wherein the plurality of grooves are generally parallel with the airflow path through the base.

20. The blade server of claim 15, wherein the inner and outer walls comprise substantially parallel plates.
